(19) United States
(12) Patent Application Publication
(10) Pub. No.: US 2005/0178428 A1
(43) Pub. Date: Aug. 18, 2005

(54) Photovoltaic system and method of making same

(75) Inventors: Heshmat Ollah Laaly, Los Angeles, CA (US); Stanley Burton Levy, Wilmington, DE (US); James Anton Chaney, Tempe, AZ (US)

Correspondence Address: Ralph A. Dowell;Dowell & Dowell, P.C., Suite 406, 2111 Eisenhower Ave., Alexandria, VA, 22314, US

(73) Assignee: Solar Roofing Systems Inc.

(21) Appl. No.: 10/964,612

(22) Filed: Oct. 15, 2004

Related U.S. Application Data
(60) Provisional application No. 60/544,497, filed on Feb. 17, 2004.

(51) Int. Cl. H01L 25/00

(52) U.S. Cl. 136/251; 438/64

(57) ABSTRACT

The present invention relates to a photovoltaic system and methods of making same. The photovoltaic system has a plurality of layers attached to each other to form a unitary structure. More specifically, the photovoltaic system includes: a base, flexible membrane layer; a photovoltaic layer having at least one photovoltaic cell associated therewith; a semi-rigid layer for supporting the photovoltaic layer and imparting rigidity thereto; and a top, transparent, protective layer for protecting the base, flexible membrane layer, the semi-rigid layer and the photovoltaic layer from exposure to the environment. The photovoltaic layer and the semi-rigid layer are disposed between the base, flexible membrane layer and the top, protective layer. Additional layers of adhesive may be disposed between the various layers to facilitate bonding thereof.

### RELATED APPLICATION

This application claims priority to U.S. Provisional Patent Application Ser. No. 60/544,497, filed Feb. 17, 2004, entitled “PHOTOVOLTAIC CELL ROOFING SYSTEM”, the disclosure of which is hereby incorporated by reference.

1. Field of the Invention

The present invention relates to a photovoltaic system and methods of making same.

2. Background of the Invention

The increasing concern for depletion of non-renewable fossil fuels and environmental issues, and the ever-growing demand for cleaner, more cost-effective sources of energy, have spurred interest in solar power technology and applications thereof.

Various photovoltaic devices having a plurality of semiconductor cells, have been developed which transform light into direct current (dc) electricity. As the electrical power generated by a photovoltaic device is proportional to the light incident on its cells, it has been necessary to install photovoltaic devices in highly illuminated areas. Given that traditionally the efficiency of the photovoltaic cells has been relatively low, fairly large solar energy collection areas have been required to generate usable amounts of power. These conditions led to photovoltaic devices in some cases being mounted on exterior structures and more particularly, on the roof structures of buildings. Roofs tend to receive high levels of illumination and tend to have sufficient available surface areas to accommodate arrays of photovoltaic devices.

There were however, certain difficulties in mounting the photovoltaic devices to the roof structures. The weight of the photovoltaic cells had to be adequately supported on the roof structure and the installation had to be capable of resisting typically high wind loads. In some applications, steel mounting brackets were employed to address these problems. However, this solution tends to be expensive. Installation tends to be time-consuming, requiring special installation techniques and hardware. In addition, these support structures tend to be heavy and the building structures must be reinforced to accommodate their use. Additionally, these structures tend to require extensive maintenance to keep the photovoltaic devices operational. The foregoing disadvantages tended to discourage the broad application of roof-mounted photovoltaic systems for residential or commercial buildings.

There have been however a number of attempts to incorporate photovoltaic cells into different types of roofing systems. For instance, U.S. Pat. Nos. 5,092,939; 5,232,518 and 4,189,881 disclose photovoltaic roofing structures of the batten and seam type. U.S. Pat. Nos. 4,040,867; 4,321,416 and 5,575,861 disclose various photovoltaic shingles.

U.S. Pat. No. 4,860,509, issued to Laaly et al., hereby incorporated herein by reference, teaches a photovoltaic roofing system having a multi-layered laminate structure. The roofing system includes a single-ply, flexible membrane layer for adhering to a roof structure. Laminated upon the membrane layer is a structurally flexible layer of photovoltaic cells encapsulated and sealed in a flexible pottant material. A protective layer covers the flexible pottant material.

In the field, the photovoltaic roofing system of Laaly et al. has tended to perform well, particularly in applications where thin-film photovoltaic cells have been used. However, where relatively rigid, crystalline silicon solar cells have been employed, certain problems have arisen which have limited their effective use in the field. More specifically, crystalline silicon solar cells tend to be brittle and more prone to cracking than their thin-film counterparts. This characteristic tends to make crystalline silicon solar cells more challenging to work with. Their fragility requires special handling measures and installation techniques. Moreover, to avoid cracking failures, the size of individual crystalline solar cells has been restricted, thereby adversely impacting on the efficiency of the cells and on their cost of production. As an example, in one known application, the foregoing constraints have prompted the use of crystalline solar cells measuring no more than about 2 inches by 2 inches.

While the use of thin-film photovoltaic cells has been found to be advantageous in certain applications, their efficiency has not yet been able to match that of crystalline silicon solar cells. Moreover, if larger crystalline silicon cells could be employed in a photovoltaic system with minimum impact on the durability of such cells, efficiency in solar energy collection could be further realized. Accordingly, there is a need for a photovoltaic system specifically adapted to accommodate the use of relatively larger rigid photovoltaic cells. It would further be desirable to have a system using rigid photovoltaic cells, which would be durable and whose handling and installation would be further facilitated. Such a photovoltaic system could be employed in numerous applications, but would be particularly advantageous in roofing applications.

### SUMMARY OF THE INVENTION

According to a broad aspect of an embodiment of the present invention, there is provided a photovoltaic system which includes: a base, flexible membrane layer; a photovoltaic layer having at least one photovoltaic cell associated therewith; a semi-rigid layer for supporting the photovoltaic layer and imparting rigidity thereto; and a top, transparent, protective layer for protecting the base, flexible membrane layer, the semi-rigid layer and the photovoltaic layer from exposure to the environment. The photovoltaic layer and the semi-rigid layer are disposed between the base, flexible membrane layer and the top, protective layer. The base, flexible membrane layer, the semi-rigid layer, the photovoltaic layer and the top, protective layer are assembled together to form a unitary structure.

In an additional feature, the semi-rigid layer may be disposed over top the base, flexible membrane layer, and the photovoltaic layer may be disposed over top the semi-rigid layer. In a further additional feature, a first adhesive layer is disposed between the base, flexible membrane layer and the semi-rigid layer. A second adhesive layer is disposed between the semi-rigid layer and the photovoltaic layer. A third adhesive layer is disposed between the photovoltaic layer and the top, protective layer.

According to another broad aspect of an embodiment of the present invention, there is provided a method of making a photovoltaic system having a plurality of stacked layers. The method includes: providing a base, flexible membrane layer and a top, transparent, protective layer; placing a semi-rigid layer and a photovoltaic layer having at least one photovoltaic cell associated therewith, between the base, flexible membrane layer and the top protective layer; and attaching the layers together to form a unitary structure. In an additional feature, placing includes stacking the semi-rigid layer over top the base, flexible membrane layer; and stacking the photovoltaic layer over top the semi-rigid layer.

In another additional feature, the method further includes, prior to attaching: placing a first adhesive layer between the base, flexible membrane layer and the semi-rigid layer; placing a second adhesive layer between the semi-rigid layer and the photovoltaic layer; and placing a third adhesive layer between the photovoltaic layer and the top, protective layer. In still another additional feature, attaching includes laminating the plurality of layers together. In yet another additional feature, attaching includes first laminating the semi-rigid layer, an adhesive layer, the photovoltaic layer, another adhesive layer and the top, protective layer together; and then affixing the semi-rigid layer to the base, flexible membrane layer.

### DESCRIPTION OF DRAWINGS

The embodiments of the present invention shall be more clearly understood with reference to the following detailed description of the embodiments of the invention taken in conjunction with the accompanying drawings, in which:

FIG. 1 is an exploded perspective view of a photovoltaic system according to an embodiment of the invention;

FIG. 2 is a schematic cross-sectional view of the photovoltaic system shown in FIG. 1;

FIG. 3 is perspective view of the photovoltaic system shown in FIG. 1;

FIG. 4 is a schematic cross-sectional view of an alternative photovoltaic system to that shown in FIG. 2;

FIG. 5 is an exploded perspective view of a photovoltaic system according to an alternative embodiment of the invention;

FIG. 6 is a schematic cross-sectional view of the photovoltaic system shown in FIG. 5; and

FIG. 7 is a perspective view of a heat vacuum laminator used to attach the various layers of the photovoltaic system to form a unitary structure.

### DETAILED DESCRIPTION OF THE EMBODIMENTS OF THE INVENTION

The description which follows, and the embodiments described therein are provided by way of illustration of an example, or examples of particular embodiments of principles and aspects of the present invention. These examples are provided for the purposes of explanation and not of limitation, of those principles of the invention. More specifically, in the description that follows an exemplary application of a photovoltaic system in the field of roofing is described. It will however be appreciated that the present invention is not limited to photovoltaic systems for use in roofing applications. It is contemplated that the photovoltaic system described herein below may be advantageously employed in a broad range of applications and may be installed onto any surface exposed to sufficient amounts of sunlight.

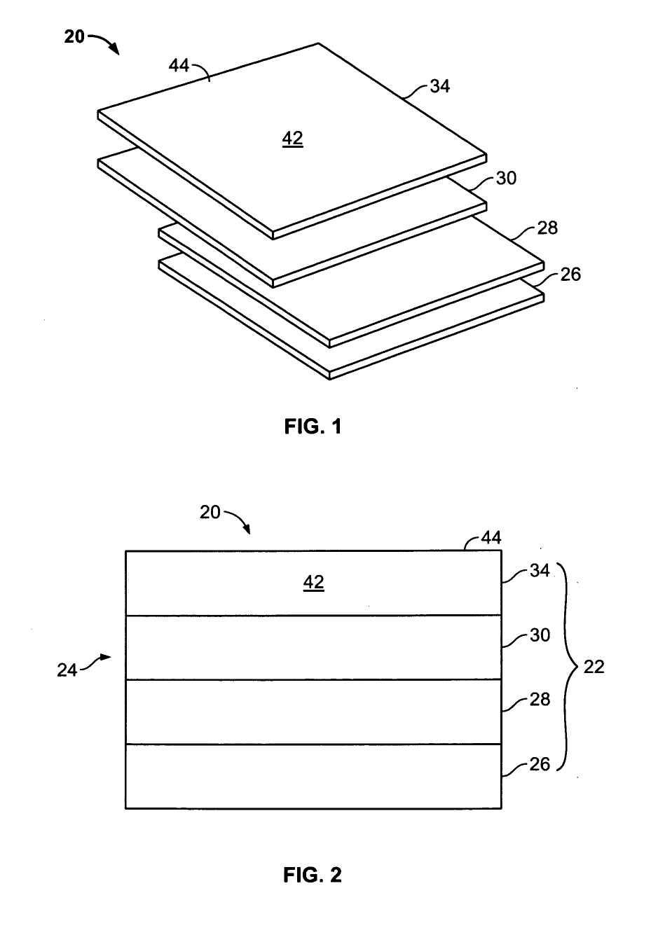

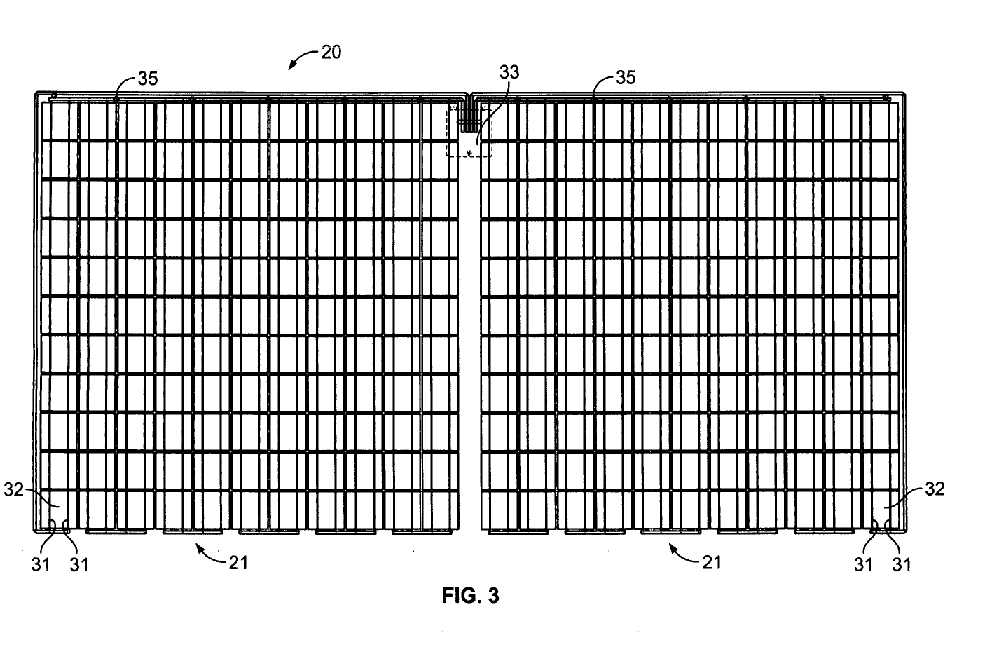

Referring to FIGS. 1, 2 and 3, there is shown a photovoltaic system designated generally with reference numeral 20. The photovoltaic system 20 is adapted for mounting onto a roof structure (not shown) of a building. The photovoltaic system 20 may be embodied in elongated sheets 21 (shown in FIG. 3) that are folded during manufacture, to facilitate transport to the installation site. The sheets embodying the photovoltaic system 20 may be laid out and attached to the roof structure using conventional installation methods generally known in the art. For instance, the photovoltaic system 20 may be mechanically fastened or adhered directly to the deck (not shown) of the roof structure, or onto the wood, concrete, corrugated steel, galvanized steel panels or any of the commonly used rigid thermal insulation boards that are positioned on and attached to the deck of the roof structure. Alternatively, attachment of the photovoltaic system 20 to the roof structure may be achieved with a negative pressure system formed by the creation of a vacuum between the photovoltaic system 20 and the roof structure. This manner of attaching the photovoltaic system to the underlying roof structure tends to be advantageous in that it tends to minimize the use of fasteners or adhesives, thereby facilitating installation of the photovoltaic system. Also, this manner of attachment tends to reduce the extent to which the roof structure may be pierced or otherwise penetrated to ensure proper securing of the photovoltaic system thereon.

The photovoltaic system 20 has a plurality of layers 22 attached to each other to form a unitary structure 24. More specifically, the photovoltaic system 20 includes: a base, flexible membrane layer 26 for attaching to the roof structure; a photovoltaic layer 30 having at least one photovoltaic cell 32 associated therewith; a semi-rigid layer 28 for imparting rigidity to the photovoltaic layer 30; and a top, transparent, protective layer 34 disposed in overlying relation to layers 26, 28 and 30 to protect these layers from exposure to the environment.

The base, flexible membrane layer 26 serves a dual function—it protects the underlying roofing structure to which it is attached and acts as a substrate upon which the other layers may be stacked. The flexible membrane layer 26 may be made of single-ply roofing membrane materials, such as, thermoplastics, modified bitumens, vulcanized elastomers, non-vulcanized elastomers, EPDM (ethylene propylene diene monomer) rubbers, or the like. Preferably, the base, flexible membrane layer 26 is constructed from thermoplastics and more preferably from polyvinylchloride (PVC). Alternatively, thermoplastic polyolefin (TPO) or thermoplastic alloy (TPA) may be used to similar advantage. If desired, the base, flexible membrane layer 26 may be reinforced with reinforcing fibers, such as woven or non-woven fiberglass fiber mats. The inclusion of such fibers tends to allow the membrane layer 26 to retain its dimensional stability over a broad range of temperatures. The single-ply roofing membrane sold under the trademark GAF® by GAF Materials Corporation of Wayne, N.J. is an example of a reinforced PVC roofing membrane that would be suitable for use in the foregoing application. It includes a lower layer of carbon black PVC, an upper layer of gray PVC, and an intermediate reinforcing layer disposed between the upper and lower layers.

Where the base, flexible membrane layer 26 is made of PVC, the thickness of the layer may vary between about 0.04 inches and 0.09 inches. In the preferred embodiment, the thickness of the membrane layer 26 is about 0.06 inches.

In this embodiment, the semi-rigid layer 28 is mounted between the base, flexible membrane layer 26 and the photovoltaic layer 30. The semi-rigid layer 28 supports the photovoltaic layer 30 and imparts structural rigidity thereto. As explained in greater detail below, this added stiffness provides the photovoltaic layer 30 with an increased resistance to cracking and wear. While in this embodiment, the semi-rigid layer 28 is made of fiberglass reinforced plastic (FRP), it will be appreciated that other materials exhibiting similar rigidity characteristics to those of FRP may be used to similar advantage. For instance, aluminum, glass, certain plastics or even commonly used house shingle could be used in the semi-rigid layer 28.

Selection of the material for the semi-rigid layer 28 will, in part, depend on the type of photovoltaic cells 32 being used in the photovoltaic layer 30. Certain photovoltaic cells may have limited flexing abilities thereby requiring more rigid support for their proper functioning. Similarly, the thickness of the semi-rigid layer 28 may be varied to impart more or less rigidity thereto. It is contemplated that, when made of FRP, the semi-rigid layer 28 will have a thickness of between about 0.060 inches and about 0.150 inches. In this case, preferably, the thickness of the semi-rigid layer 28 will be about 0.125 inches. The surface area of the semi-rigid layer 28 will vary depending on the application of the photovoltaic system 20. For instance, in a particular installation, the surface area of the semi-rigid layer may measure approximately 4 feet by 8 feet, or more.

With reference to FIG. 3, the photovoltaic layer 30 has a plurality of photovoltaic cells 32. Spacing is provided between individual cells 32 to enhance flexibility of the photovoltaic layer 30 to thereby allowing folding and unfolding of the photovoltaic system 20 during manufacture and installation. The plurality of photovoltaic cells 32 are distributed in a two dimensional array of rows and columns arranged continuously along the photovoltaic layer 30. It will however be appreciated that this need not be the case in all applications. The plurality of photovoltaic cells could be laid out in other suitable patterns as well. Electric connectors, such as flat wires 31 or the like, are provided for interconnecting the plurality of photovoltaic cells 32 to each other to conduct the flow of electrical current with the desired voltage and current characteristics. The flat wires feed into a junction box 33 from where the output connection is made. Bypass diodes 35 are placed at predetermined intervals (i.e. at every two rows of photovoltaic cells) along the photovoltaic layer 30. The bypass diodes 35 tend to ensure that power continues to be carried across the photovoltaic layer 30 in the event some photovoltaic cells are rendered inoperative by reason of being disposed in the shade or having sustained damage. Interconnection of the plurality of photovoltaic cells 32 may be achieved in a variety of ways generally known in the art.

Preferably, the photovoltaic cells 32 are crystalline silicon solar cells 40, which to date have proven to be very efficient in collecting solar energy for conversion to electrical power. As previously mentioned, crystalline silicon solar cells have tended to be brittle and as such have been prone to breakage as a result of repeated rolling or bending of the photovoltaic layer, or excessive loading thereof. Accordingly, the fragility of the crystalline silicon solar cells has posed problems in known photovoltaic systems employing such cells, often requiring such systems to be handled with the special care during transport, installation and maintenance. It has also discouraged use of relatively larger and more delicate solar cells that may have improved efficiency compared to other types of solar cells, in photovoltaic systems. It will however be appreciated that the foregoing disadvantages have been mitigated in the photovoltaic system 20 by providing a support or a backing for the crystalline silicon solar cells 40 in the nature of the semi-rigid layer 28. The semi-rigid layer 28 tends to extend the service life of the photovoltaic cells 32 by providing additional stiffness thereto leading to an improved resistance to failure resulting from cracking and wear. As a result, the overall durability of the photovoltaic system 20 tends to be enhanced. Installation may also be facilitated, as the semi-rigid layer tends to allow the system 20 to be more easily handled and attached to the roofing structure. It will thus be appreciated that the photovoltaic system 20 strikes a fine balance between the stiffness provided by the semi-rigid layer 28 to protect the photovoltaic layer 30 from cracking, and the flexibility required for ease of transport and installation.

While in this embodiment crystalline silicon solar cells have been employed, it will be understood that depending on the particular application, in alternative embodiments, other types of photovoltaic cells whether of organic or inorganic origin, could be employed, for instance, thin-film solar cells, non-silicon compound thin-film solar cells, nano-structure solar cells, poly-crystalline solar cells, or the like.

Preferably, each of the solar cells 40 is square-shaped and sized larger than 2 inches by 2 inches. More preferably, the crystalline silicon solar cells 40 measure 4 inches by 4 inches. It will, however, be appreciated that solar cells of larger dimensions (i.e. 5 inches by 5 inches, or 6 inches by 6 inches) could also be used in the photovoltaic system to similar advantage. The solar cells could also have other alternate shapes. Each crystalline silicon solar cell 40 preferably has a thickness of between about 0.010 inches to about 0.018 inches.

In the current embodiment, the top, protective layer 34 is placed over top the photovoltaic layer 30 and encapsulates the stacked layers 26, 28 and 30. While the primary function of the protective layer 34 is to impart weather resistance to the photovoltaic layer 30 and to protect it from adverse environmental conditions and exposure to the elements (i.e. pollution, moisture), it will be appreciated that protective layer 34 also affords protection to the other layers and the roof structure supporting the photovoltaic system 20. In particular, the protective layer 34 may also operate to reduce the need for maintenance and repair of the flexible membrane layer 26 and prolong the expected service life of the membrane.

In the preferred embodiment, the transparent, protective layer 34 is a dirt-repellent, fluoropolymer film 42 selected for its durability, excellent weather resistance properties and its ability to protect against moisture. Moreover, the fluoropolymer film 42 possesses high solar radiation transmissivity such that it tends not to absorb solar radiation in significant amounts. The fluoropolymer film 42 may be made from any of the following compounds: ethylene-tetrafluoroethylene (ETFE), fluorinated ethylene propolyne (FEP), perfluoro alkoxy (PFA), tetrafluoroetylene/hexafluoroproplyne/vinyladine fluoride (THV), polyvinylidene fluoride or any other highly transparent compound exhibiting UV stable/resistant characteristics. Preferably, the fluoropolymer film 42 is made of ETFE and has a thickness of about 0.002 inches. Examples of suitable ETFE for use in the protective layer 34 are ETFE matte finish film, made by Saint-Gobain Performance Plastics of Wayne, New Jersey, sold under the trademark Norton™ ETFE film, and ETFE made by E.I. Du Pont de Nemours and Company of Wilmington, Del., sold under the trademark Tefzel™. It will be appreciated that the mechanical properties of the fluoropolymer film 42, such as abrasion resistance, may be improved by modifying the orientation of the fluoropolymer film 42 on the protective layer 34.

While it is preferred that the top surface 44 of the fluoropolymer layer 42 be relatively smooth, this need not be the case in every application. If desired, the top surface of the fluoropolymer layer could be textured using the stippling method described later below. In an alternative embodiment, the top, transparent, layer may be made of glass having a top surface that is either smooth or textured. It is contemplated that where glass is employed as the protective layer it may also be considered for use as the semi-rigid layer.

The plurality of layers 22 (more specifically, layers 26, 28, 30 and 34) may be attached or assembled together by way of an adhesive. Preferably, the adhesive used is a heat-activated adhesive. More preferably, the heat-activated adhesive is ethylene-vinyl-acetate (EVA). Polyvinylbuterol (PVB) could also be used as a substitute for EVA. Similarly, it is contemplated that any pottant layer that acts as a binder and a cushion may be substituted for EVA.

Other suitable adhesives include non-heat activated adhesives, such as pressure-sensitive adhesives or contact adhesives, for instance, glues. Non-heat activated adhesives could be employed in instances where the material comprising the base, flexible membrane layer possesses a softening/melting point which is lower than that of EVA, thereby making this adhesive unsuitable for use in this application. This is the case, for instance, with some types of thermoplastic polyolefins (TPO). In such cases, glue may be used to attach the base, flexible membrane layer 26 to the semi-rigid layer 28. In further alternative embodiments, the base, flexible membrane layer and the semi-rigid layer could be attached to each other by melt bonding, thereby obviating the need for adhesives.

It will thus be understood that the photovoltaic system 20 may be produced by placing the various layers one over top the other and attaching the layers together to form the unitary structure 24. More specifically, the preferred method of making photovoltaic system 20 includes: (a) stacking the semi-rigid layer 28 onto the base, flexible membrane layer 26; (b) stacking the photovoltaic layer 30 onto the semi-rigid layer 28; (c) coating the layers 26, 28 and 30 with the top, protective layer 34; and (d) attaching the layers 26, 28, 30 and 34 together to form the unitary structure 24. It should be noted that each of the layers does not need to have the same dimensions and that it may be preferable if the base, flexible membrane layer 26 and the top protective layer 34 are larger than the semi-rigid layer 28 and/or the photovoltaic layer 34.

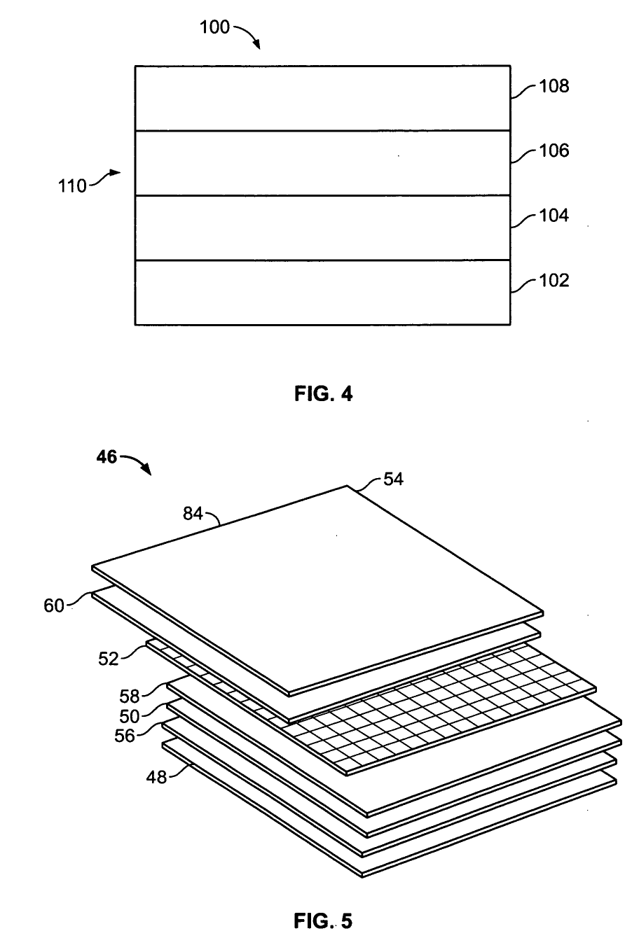

While it is preferred that the plurality of layers 22 be stacked in the following order: the base, flexible membrane layer 26, the semi-rigid layer 28, the photovoltaic layer 30 and top, protective layer 34, it will be appreciated that with minor modifications and judicious selection of materials, this order could be altered. Referring to FIG. 4, there is shown an alternative embodiment, in which the two intermediate layers (the semi-rigid and photovoltaic layers) of a photovoltaic system 100 have been inverted. The photovoltaic system 100 is generally similar to photovoltaic system 20 in that it includes a base, flexible membrane layer 102, a photovoltaic layer 104, a semi-rigid layer 106 and a top, transparent, protective layer 108; all of which are attached together to form a unitary structure 110. However, in this embodiment, the plurality of layers are arranged such that the photovoltaic layer 104 is disposed between the base, flexible membrane layer 102 and the semi-rigid layer 106. To ensure the proper functioning of photovoltaic system 100, the semi-rigid layer 106 is transparent so as to allow sufficient amounts of sunlight to reach the photovoltaic layer 104. It will thus be understood that a different method would be employed in making photovoltaic system 100. Such a method would include: (a) stacking the photovoltaic layer 104 onto the base, flexible membrane layer 102; (b) stacking the semi-rigid layer 106 onto the photovoltaic layer 104; (c) coating the layers 102, 104 and 106 with the top, protective layer 108; and (d) attaching the layers 102, 104, 106 and 108 together to form the unitary structure 110. In a further modified embodiment, the top transparent protective layer could be eliminated altogether leaving the photovoltaic layer sandwiched between the semi-rigid layer (now the topmost layer) and the base, flexible membrane layer. In such an embodiment, the semi-rigid layer could be made of glass.

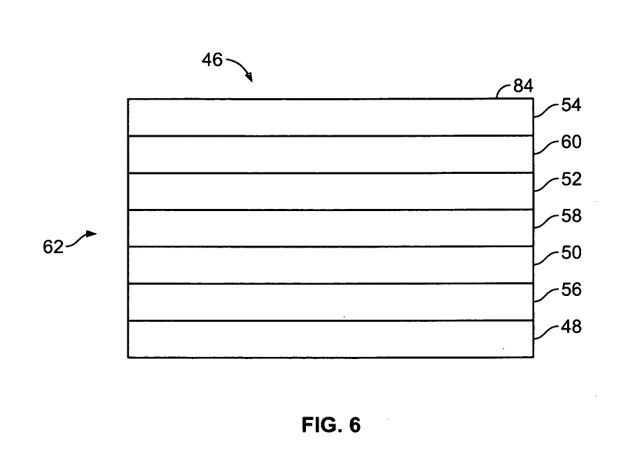

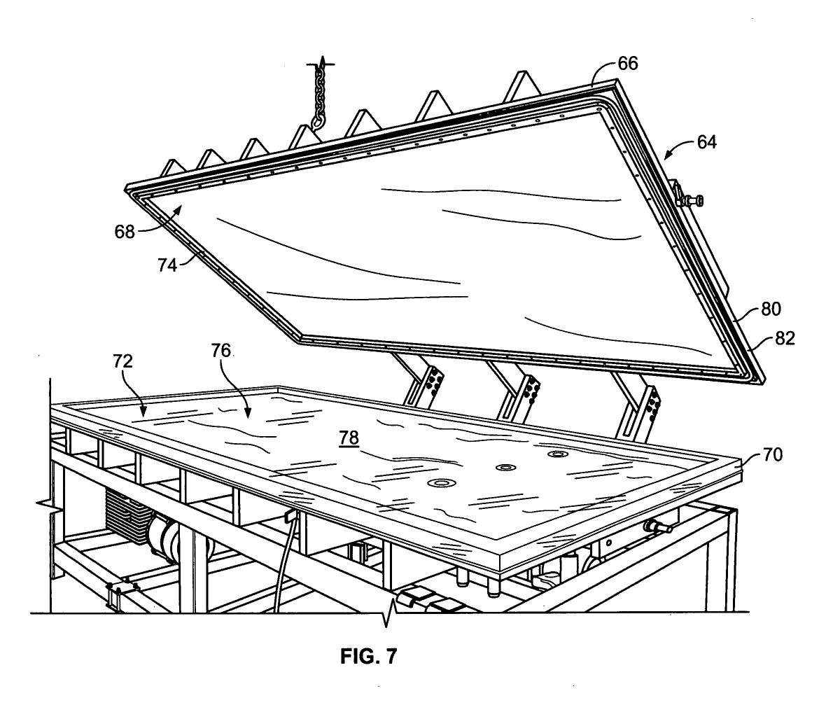

In an alternative embodiment, the adhesive used to bind the various layers may be applied so as to form independent layers between the layers. With reference to FIGS. 5 and 6, there is shown an alternate photovoltaic system designated generally with reference numeral 46. Photovoltaic system 46 is generally similar to photovoltaic system 20 described earlier in that it has a flexible membrane layer 48, a semi-rigid layer 50, a photovoltaic layer 52 and a transparent, protective layer 54 arranged in a stacked configuration. The layers 48, 50, 52 and 54 correspond generally to the layers 26, 28, 30 and 34 of photovoltaic system 20. However, mounted between each of adjacent layers 48 and 50, 50 and 52 and 52 and 54, is a layer of adhesive. More specifically, an adhesive layer 56 is disposed between the flexible membrane layer 48 and the semi-rigid layer 50; an adhesive layer 58 is disposed between the semi-rigid layer 50 and the photovoltaic layer 52; and an adhesive layer 60 is disposed between the photovoltaic layer 52 and the protective layer 54. In this embodiment, the adhesive layers 56, 58 and 60 are EVA. In like fashion to layers 26, 28, 30 and 34 of photovoltaic system 20, when layers 48, 56, 50, 58, 52, 60 and 54 are attached together they form a unitary structure 62. In a further alternative embodiment, a photovoltaic system similar to photovoltaic system 46 could be constructed in which the semi-rigid layer and the photovoltaic layers are inverted such that the photovoltaic layer would be disposed between the base, flexible membrane layer and the semi-rigid layer.

It is contemplated that the thickness of the adhesive layer 56 will be between about 0.008 inches and about 0.018 inches. The thickness of layer 56 may be adjusted as needed to effect attachment or to provide enhanced cushioning.

The adhesive layers 58 and 60 serve as pottant layers to encapsulate the photovoltaic cells of layer 52 and seal them from the effects of the environment, particularly moisture and environmental pollutants. In this embodiment, the thickness of each adhesive layer 58, 60 is about 0.018 inches, but may be varied as required.

Broadly speaking, the photovoltaic system 46 may be produced by placing the layers 48, 56, 50, 58, 52, 60 and 54 one over top the other and permanently attaching the various layers to form the unitary structure 62. More specifically, the method for making the photovoltaic system 46 includes: (a) placing the adhesive layer 56 over top the base, flexible membrane layer 48; (b) placing the semi-rigid layer 50 over top the adhesive layer 56; (c) placing the adhesive layer 58 over top the semi-rigid layer 50; (d) placing the photovoltaic layer 52 over top the adhesive layer 58; (e) placing the adhesive layer 60 over top the photovoltaic cell layer 52; (f) placing the protective layer 54 over top the adhesive layer 60; and (g) attaching layers 48, 56, 50, 58, 52, 60 and 54 together to form the unitary structure 62. It will be appreciated that the foregoing method could be easily modified to make a photovoltaic system whose semi-rigid and photovoltaic layers are inverted, as discussed above.

A preferred method of attaching the various layers involves laminating at least several of the plurality of stacked layers together. Lamination of the stacked layers occurs in a vacuum laminator 64 (shown in FIG. 6) of the type generally known in the art. More specifically, the vacuum laminator 64 has an upper portion 66 defining an upper chamber 68, a lower portion 70 defining a lower chamber 72, a flexible, silicone rubber diaphragm 74 mounted to the upper portion 66 for separating the upper chamber 68 from the lower chamber 72, and a heater plate 76 located in the lower portion 70 of the laminator 64. It will be appreciated that alternative laminators having two heater plates, one located in the upper portion and one located in the lower portion thereof, may also be used.

The lower portion of the laminator 64 includes a base surface 78 upon which may be placed the plurality of stacked layers to be laminated. The heater plate 76 is formed within the base surface 78. The upper portion 66 of the laminator 64 is hingedly mounted to the lower portion 68 thereof and is adapted to form a lid 80 which is moveable between an open position 82 and a closed position (not shown). When moved to the closed position, the lid 80 covers the base surface 78.

The lamination process includes a vacuum cycle, a pressure cycle, a heat cycle and a curing cycle. More specifically, the stacked layers 48, 56, 50, 58, 52, 60 and 54 are placed into the vacuum laminator 64 onto the base surface 78 and the lid 80 is moved to its closed position. Air is evacuated from both the upper and lower chambers 68 and 72. This vacuum cycle lasts between 5 and 20 minutes and allows the air between the various stacked layers to be evacuated before the pressure cycle begins, thereby tending to eliminate trapped gas bubbles. Subsequently, the vacuum in the upper chamber 68 ceases to be drawn and the upper chamber 68 is placed in fluid communication with the atmosphere. This pressure differential causes the diaphragm 70 to be uniformly drawn over the topmost surface of the stacked layers thereby causing the diaphragm 70 to be compressed against the heater plate 76. The flexible diaphragm 70 conforms to the top surface of the stacked layers thereby assuring positive and uniform contact between the layers and eliminating voids.

During the heat cycle, starting from room temperature or a temperature of up to 50° C., the heater plate 76 is heated to a top temperature of approximately 160° C. The ramping of the heater plate 76 to the top temperature may take approximately 5 to 10 minutes. Once the top temperature has been reached it is maintained for approximately 3 to 5 minutes to allow for the activation of the adhesive layers 56, 58 and 60 to thereby initiate bonding of the layers to each other. During this period, pressure continues to be applied on the layers. Also, the protective layer 54 is sufficiently softened to form a coating around the other layers. In laminator 64 the heat emanates from the lower portion 72 only. More specifically, the heat is transferred from the heater plate 76 to the flexible membrane layer 48 to be distributed to the stacked layers. It will be appreciated that an alternative laminator having upper and lower heater plates located respectively in upper and lower portions of the laminator could also be employed advantageously to produce a photovoltaic system. Where such a laminator is used, prior to ceasing the vacuum in the upper chamber, the diaphragm could be pre-heated by the upper heater plate. In such a case, the provision of an upper and lower heater plate would tend to ensure a more even distribution of heat amongst the stacked layers and would tend to reduce the duration of the heat cycle thereby expediting production.

After the heat cycle, the stacked layers are left in the laminator 64 to cool for a period of 5 to 15 minutes. Once the stacked layers have cooled below approximately 70° C., the laminator lid 80 is moved to its open position 82 and the stacked layers are removed from the laminator 64 for further curing, conditioning and cooling at room temperature.

Once the system is at approximately room temperature, the photovoltaic system 46 may be finished. Finishing may include: (a) trimming any excess material from the photovoltaic system, including removing a thickness of the protective layer 54, if necessary; (b) installing electrical connectors to the photovoltaic system 46, or the like; and (c) performing quality control testing on the photovoltaic system 46. The installation of electrical connectors to the photovoltaic system 46 may include attachment of the connectors to output lead connectors (not shown) and sealing of the exit area with adhesive and a cover patch. Quality control testing may include testing the photovoltaic system 46 under an artificial light source using a digital voltage and current meter to verify that the system 46 is functioning according to specifications.

Where it is desired that the top surface 84 of the protective layer 54 (made of ETFE) be stippled, for example, for safety or aesthetic reasons, a fiberglass screen or the like may be placed over top the protective layer 54 prior to the stacked layers being placed into the laminator 64. This will cause the screen pattern to be permanently embossed onto the top surface 84 creating a textured surface. It will be appreciated that this step may not be suitable where glass is used as the protective layer 54. In such a case, if stippling is desired, the glass may already be provided with stippling prior to production.

It will be understood that the lamination process and or equipment may be modified as appropriate to suit the needs of particular arrangements of layers or the like.

Where the material comprising the flexible membrane layer possesses a softening/melting point that is lower than that of the adhesive layers or in cases where manufacturing or installation efficiencies may be realized, an alternate production method employing two stage construction may be used. Broadly speaking, the alternate method involves stacking layers, other than the flexible membrane layer, one over top the other as in the arrangement described above attaching those layers together (by way of lamination, for example) and then later affixing the bonded layers to the flexible membrane layer using a non-heat activated adhesive. More specifically, the alternate method includes the steps of: (a) placing the adhesive layer 58 over top the semi-rigid layer 50; (b) placing the photovoltaic cell layer 52 over top the adhesive layer 58; (c) placing the adhesive layer 60 over top the photovoltaic cell layer 52; (d) placing the top, protective layer 54 over top the adhesive layer 60; (e) attaching the layers 50, 58, 52, 60 and 54 to each other; (f) later affixing the semi-rigid layer 50 onto the flexible membrane layer 48 in a stacked relation.

Attaching the layers 50, 58, 52, 60 and 54 to each other may include laminating those layers together using the vacuum laminator 64 and heat lamination process described previously. Affixing the flexible membrane layer 48 to the semi-rigid layer 50 may include adhering the flexible membrane layer 48 to the semi-rigid layer 50 by way of a non-heat activated adhesive. It will be appreciated that the affixing operation may be performed either at the manufacturing plant, after the laminated layers have been sufficiently cooled, or at a later time, for instance, at the installation site. Where attachment of the laminated layers with the flexible membrane layer occurs at the installation site, it may be desirable to secure the flexible membrane layer 52 to the roof structure prior to carrying out the affixing operation.

Although the foregoing description and accompanying drawings relate to specific preferred embodiments of the present invention and specific methods of production as presently contemplated by the inventor, it will be understood that various changes, modifications and adaptations, may be made without departing from the spirit of the invention.

1. A photovoltaic system comprising:
a base, flexible membrane layer;
a photovoltaic layer having at least one photovoltaic cell associated therewith;
a semi-rigid layer for supporting the photovoltaic layer and imparting rigidity thereto; and
a top, transparent, protective layer for protecting the base, flexible membrane layer, the semi-rigid layer and the photovoltaic layer from exposure to the environment;
the photovoltaic layer and the semi-rigid layer being disposed between the base, flexible membrane layer and the top, protective layer;
the base, flexible membrane layer, the semi-rigid layer, the photovoltaic layer and the top, protective layer being attached together to form a unitary structure.

2. The photovoltaic system of claim 1 wherein:
the photovoltaic layer is disposed over top the base, flexible membrane layer; and
the semi-rigid layer is disposed over top the photovoltaic layer and is transparent.

3. The photovoltaic system of claim 1 wherein:
the semi-rigid layer is disposed over top the base, flexible membrane layer; and
the photovoltaic layer is disposed over top the semi-rigid layer.

4. The photovoltaic system of claim 3 wherein the base, flexible membrane layer, the semi-rigid layer and the photovoltaic layer are attached one to the other by an adhesive.

5. The photovoltaic system of claim 4 wherein the adhesive is a heat-activated adhesive.

6. The photovoltaic system of claim 5 wherein the heat-activated adhesive is ethylene-vinyl-acetate.

7. The photovoltaic system of claim 4 wherein the adhesive is a non-heat activated adhesive.

8. The photovoltaic system of claim 7 wherein the non-heat activated adhesive is a pressure-sensitive adhesive.

9. The photovoltaic system of claim 8 wherein the non-heat activated adhesive is glue.

10. The photovoltaic system of claim 3 wherein the base, flexible membrane layer and the semi-rigid layer are attached to each other by melt bonding.

11. The photovoltaic system of claim 3 further comprises:
a first, adhesive layer disposed between the base, flexible membrane layer and the semi-rigid layer;
a second, adhesive layer disposed between the semi-rigid layer and the photovoltaic layer; and
a third, adhesive layer disposed between the photovoltaic layer and the top, protective layer.

12. The photovoltaic system of claim 11 wherein the first, adhesive layer has a thickness of between about 0.008 inches and about 0.018 inches.

13. The photovoltaic system of claim 11 wherein the second and third, adhesive layers have a thickness of about 0.018 inches.

14. The photovoltaic system of claim 11 wherein at least one of the first, second and third adhesive layers is ethylene-vinyl-acetate.

15. The photovoltaic system of claim 11 wherein at least one of the first, second and third adhesive layers is polyvinylbutyrol.

16. The photovoltaic system of claim 11 wherein:
the second and third, adhesive layers are ethylene-vinyl-acetate;
the base, flexible membrane layer is made of a thermoplastic polyolefin having a melting point less than that of ethylene-vinyl-acetate; and
the first adhesive layer is a non-heat activated adhesive.

17. The photovoltaic system of claim 1 wherein the base, flexible membrane layer is made of a single-ply roofing material selected from the group consisting of:
(a) a thermoplastic roofing membrane;
(b) a vulcanized elastomeric membrane;
(c) a non-vulcanized elastomeric membrane; and
(d) a modified bituminous roofing membrane.

18. The photovoltaic system of claim 17 wherein the base, flexible membrane layer is reinforced.

19. The photovoltaic system of claim 1 wherein the base, flexible membrane layer is made of polyvinylchloride.

20. The photovoltaic system of claim 19 wherein the base, flexible membrane layer has a thickness of between about 0.04 inches and about 0.09 inches.

21. The photovoltaic system of claim 20 wherein the thickness of the base, flexible membrane layer is about 0.06 inches.

22. The photovoltaic system of claim 3 wherein the semi-rigid layer is fiberglass reinforced plastic.

23. The photovoltaic system of claim 22 wherein the semi-rigid layer has a thickness of between about 0.060 inches and about 0.150 inches.

24. The photovoltaic system of claim 23 wherein the thickness of the semi-rigid layer is about 0.125 inches.

25. The photovoltaic system of claim 3 wherein the semi-rigid layer is made from a material selected from the group of consisting of:
(a) aluminum; and
(b) glass.

26. The photovoltaic system of claim 1 wherein the photovoltaic cell is a crystalline silicon solar cell.

27. The photovoltaic system of claim 26 wherein the photovoltaic cell is sized larger than about 2 inches by 2 inches.

28. The photovoltaic system of claim 27 wherein the photovoltaic cell is sized about 4 inches by 4 inches.

29. The photovoltaic system of claim 27 wherein the photovoltaic cell is sized larger than about 4 inches by 4 inches.

30. The photovoltaic system of claim 26 wherein the photovoltaic cell has a thickness of between about 0.01 inches and about 0.018 inches.

31. The photovoltaic system of claim 1 wherein the photovoltaic layer includes a plurality of photovoltaic cells distributed in a two dimensional flat array of rows and columns.

32. The photovoltaic system of claim 31 further including electrical connector for interconnecting the plurality of photovoltaic cells to allow for the extraction of electrical power therefrom.

33. The photovoltaic system of claim 1 wherein the top, protective layer is a dirt-repellent, fluoropolymer film.

34. The photovoltaic system of claim 33 wherein the fluoropolymer film is a matte finish film.

35. The photovoltaic system of claim 33 wherein the fluoropolymer film is made from a compound selected from the group consisting of:
(a) ethylene-tetrafluoroethylene;
(b) fluorinated ethylene propolyne;
(c) perfluoro alkoxy;
(d) tetrafluoroetylene/hexafluoroproplyne/vinylidene fluoride; and
(e) polyvinylidene fluoride.

36. The photovoltaic system of claim 33 wherein the fluoropolymer film is made from ethylene-tetrafluoroethylene and has a thickness of about 0.002 inches.

37. The photovoltaic system of claim 1 wherein the top, protective layer is made of glass.

38. The photovoltaic system of claim 1 wherein the top, protective layer has a smooth top surface.

39. The photovoltaic system of claim 1 wherein the top, protective layer has a textured top surface.

40. A photovoltaic system comprising:
a base, flexible membrane layer;
a photovoltaic layer having at least one photovoltaic cell associated therewith;
a top, transparent, semi-rigid layer for imparting rigidity to the photovoltaic layer and for protecting the photovoltaic layer from exposure to the environment;
the photovoltaic layer being disposed between the base, flexible membrane layer and the top, semi-rigid layer;
the base, flexible membrane layer, the photovoltaic layer and the top, semi-rigid layer being attached together to form a unitary structure.

41. The photovoltaic system of claim 40 wherein the semi-rigid layer is made of glass.

42. A method of making a photovoltaic system comprising:
providing a base, flexible membrane layer and a top, semi-rigid layer;
placing a photovoltaic layer having at least one photovoltaic cell associated therewith, between the base, flexible membrane layer and the top, semi-rigid layer;
attaching the layers together to form a unitary structure.

43. A method of making a photovoltaic system comprising:
providing a base, flexible membrane layer and a top, transparent, protective layer;
placing a semi-rigid layer and a photovoltaic layer having at least one photovoltaic cell associated therewith, between the base, flexible membrane layer and the top protective layer;
attaching the layers together to form a unitary structure.

44. The method of claim 43 wherein placing includes:
stacking the photovoltaic layer over top the base, flexible membrane layer; and
stacking the semi-rigid layer over top the photovoltaic layer.

45. The method of claim 43 wherein placing includes:
stacking the semi-rigid layer over top the base, flexible membrane layer; and
stacking the photovoltaic layer over top the semi-rigid layer.

46. The method of claim 45 further comprising, prior to attaching:
placing a first adhesive layer between the base, flexible membrane layer and the semi-rigid layer;
placing a second adhesive layer between the semi-rigid layer and the photovoltaic layer; and
placing a third adhesive layer between the photovoltaic layer and the top, protective layer.

47. The method of claim 46 wherein attaching includes attaching at least the base, flexible membrane layer to the top protective layer.

48. The method of claim 46 wherein attaching includes laminating the layers together.

49. The method of claim 48 wherein laminating includes:
placing the layers into a laminator having:
an upper portion defining an upper chamber,
a lower portion defining a lower chamber,
a diaphragm mounted to the upper portion for separating the upper chamber from the lower chamber, and
a heater plate located in the lower portion;
evacuating the air from the upper and lower chambers of the laminator;
compressing the layers between the diaphragm and the heater plate;
heating the heater plate to a sufficient temperature to activate the first, second and third adhesive layers to thereby initiate bonding of the layers to each other; and
cooling the layers.

50. The method of claim 49 further comprising finishing the photovoltaic system following cooling, finishing including:
trimming any excess material from the photovoltaic system;
installing electrical connectors to the photovoltaic system; and
performing quality control testing on the photovoltaic system.

51. The method of claim 48 wherein laminating includes:
placing the layers into a laminator having:
an upper portion defining an upper chamber,
a lower portion defining a lower chamber,
a diaphragm mounted to the upper portion for separating the upper chamber from the lower chamber, and
an upper heater plate located in the upper portion, and
a lower heater plate located in the lower portion;
evacuating the air from the upper and lower chambers of the laminator;
heating the first upper heater plate to effect pre-heating of the diaphragm;
compressing the layers between the pre-heated diaphragm and the lower heater plate;
heating the lower heater plate to a sufficient temperature to activate the first, second and third adhesive layers to thereby initiate bonding of the layers to each other; and
cooling the layers.

52. The method of claim 45 further comprising, prior to attaching:
placing a first adhesive layer between the semi-rigid layer and the photovoltaic layer; and
placing a second adhesive layer between the photovoltaic layer and the top, protective layer.

53. The method of claim 52 wherein attaching includes:
first laminating the semi-rigid layer, the first adhesive layer, the photovoltaic layer, the second adhesive layer and the top, protective layer together; and
then affixing the semi-rigid layer to the base, flexible membrane layer.

54. The method of claim 53 wherein the step of laminating further includes:
placing the semi-rigid layer, the first adhesive layer, the photovoltaic layer, the second adhesive layer and the top, protective layer into a laminator having:
an upper portion defining an upper chamber,
a lower portion defining a lower chamber,
a diaphragm mounted to the upper portion for separating the upper chamber from the lower chamber, and
a heater plate located in the lower portion of the laminator;
evacuating the air from the upper and lower chambers of the laminator;
compressing the semi-rigid layer, the first adhesive layer, the photovoltaic layer, the second adhesive layer and the top, protective layer between the diaphragm and the heater plate;
heating the heater plate to a sufficient temperature to activate the first and second adhesive layers to thereby initiate bonding of the semi-rigid layer, the photovoltaic layer, to each other; and
cooling the laminated layers.

55. The method of claim 54 wherein affixing includes adhering the base, flexible membrane layer to the semi-rigid layer by way of a non-heat activated adhesive.
